(19) United States
(12) Patent Application Publication
(10) Pub. No.: US 2025/0035006 A1
(43) Pub. Date: Jan. 30, 2025

(54) SEALING DEVICE AND ROTATING MACHINE

(71) Applicant: MITSUBISHI POWER, LTD., Tokyo (JP)

(72) Inventors: Tatsuro FURUSHO, Tokyo (JP); Shin NISHIMOTO, Tokyo (JP); Shintaro OKUMURA, Tokyo (JP); Kenichi SAKASHITA, Tokyo (JP); Masaya KAWANO, Tokyo (JP); Kohei OZAKI, Tokyo (JP); Azumi YOSHIDA, Tokyo (JP)

(21) Appl. No.: 18/716,347

(22) PCT Filed: Jan. 13, 2023
(86) PCT No.: PCT/JP2023/000705

§ 371 Date: Jun. 4, 2024

(30) Foreign Application Priority Data
Jan. 17, 2022 (JP) 2022-005286

(51) Int. Cl. F01D 11/14

(52) U.S. Cl. CPC F01D 11/14; F05D 2240/55

(57) ABSTRACT

A sealing device including: a sealing member that is disposed between a rotating member of a rotating machine and a stationary member disposed on the outer side of the rotating member in the radial direction of the rotating member, and that creates a seal between the rotating member and the stationary member; and a biasing member that biases the sealing member toward the radially outer side. The sealing member has a base extending in the circumferential direction of the rotating member, a rib that extends in the circumferential direction and protrudes outward in the radial direction from the base, and a seal fin that extends in the circumferential direction and protrudes inward in the radial direction of the rotating member from the base. The rib has a cut-away part in which the biasing member is disposed between one end and the other end of the rib in the circumferential direction.

### TECHNICAL FIELD

The present disclosure relates to a sealing device and a rotating machine.

The present application claims priority based on Japanese Patent Application No. 2022-005086 filed in Japan on Jan. 17, 2022, the contents of which are incorporated herein by reference.

### BACKGROUND ART

A rotating machine such as a gas turbine or a steam turbine includes a sealing device that reduces an amount of leakage of a working fluid flowing from a high-pressure side to a low-pressure side in the vicinity of a rotor serving as a rotating member.

PTL 1 discloses a sealing device including a sealing member provided on a radial outer side of a rotor and movable in a radial direction, and a movable sealing member including an elastic body that biases the sealing member toward the radial outer side.

In the sealing device having such a configuration, when the rotating machine is activated and deactivated, the sealing member is biased toward the radial outer side by the elastic body, and a seal gap between the rotor and the movable sealing member is sufficiently secured.

Meanwhile, during the operation of the rotating machine, a working fluid (for example, working steam) on the high-pressure side circulates around a back surface of the sealing member on the radial outer side, so that a back-surface pressure is applied to the sealing member. The back-surface pressure displaces the sealing member to a radial inner side against a biasing force of the elastic body.

### CITATION LIST

### Patent Literature

[PTL 1] Japanese Unexamined Patent Application Publication No. 2000-97352

### SUMMARY OF INVENTION

### Technical Problem

For example, in an upper-half portion of a gas turbine, a steam turbine, or the like, it is necessary to move the sealing member vertically upward against a self-weight of the sealing member by means of the biasing force of the elastic body. Therefore, in order to reliably secure a seal gap between the rotor and the movable sealing member when the rotating machine is activated and deactivated, the biasing force of the elastic body has to be sufficiently large. However, when the biasing force of the elastic body is excessively large, it becomes difficult to displace the sealing member to the radial inner side during the operation of the rotating machine. Since the self-weight of the sealing member increases as the dimension of the sealing member in the radial direction increases, the biasing force of the elastic body has to be increased. Therefore, it tends to become difficult to set the biasing force of the elastic body as the dimension of the sealing member in the radial direction increases.

In addition, for example, in a lower-half portion of a gas turbine, a steam turbine, or the like, during the operation of the rotating machine, the sealing member has to be displaced to the radial inner side against the self-weight of the sealing member and the biasing force of the elastic body. Therefore, in order to reliably displace the sealing member to the radial inner side during the operation of the rotating machine, the biasing force of the elastic body has to be relatively decreased. However, when the biasing force of the elastic body is excessively small, it becomes difficult to secure a seal gap between the rotor and the movable sealing member when the rotating machine is activated and deactivated. Therefore, it tends to become difficult to set the biasing force of the elastic body as the dimension of the sealing member in the radial direction increases.

At least one embodiment of the present disclosure is made in view of the above circumstances, and an object of the present disclosure is to provide a sealing device and a rotating machine capable of securing a seal gap between a rotating member and a sealing member when the rotating machine is activated and deactivated, and of reducing an amount of leakage of a working fluid during the operation of the rotating machine.

### Solution to Problem

(1) A sealing device according to at least one embodiment of the present disclosure includes a sealing member that is disposed between a rotating member of a rotating machine and a stationary member disposed on a radial outer side of the rotating member with respect to the rotating member, and that seals between the rotating member and the stationary member; and a biasing member that biases the sealing member toward the radial outer side, in which the sealing member includes a base portion that extends in a circumferential direction of the rotating member, a rib that extends in the circumferential direction and that protrudes from the base portion toward the radial outer side, and a seal fin that extends in the circumferential direction and that protrudes from the base portion toward a radial inner side of the rotating member, and the rib has a notch portion in which the biasing member is disposed between one end and the other end of the rib in the circumferential direction.

(2) A rotating machine according to at least one embodiment of the present disclosure includes the rotating member; the stationary member; and the sealing device having the configuration of (1) described above.

### Advantageous Effects of Invention

According to at least one embodiment of the present disclosure, it is possible to provide a sealing device and a rotating machine capable of securing a seal gap between a rotating member and a sealing member when the rotating machine is activated and deactivated, and of reducing an amount of leakage of a working fluid during the operation of the rotating machine.

### BRIEF DESCRIPTION OF DRAWINGS

FIG. 1 is a diagram for describing a steam turbine as an example of a rotating machine including a sealing device according to some embodiments.

FIG. 2 is a schematic cross-sectional view of a casing main body that constitutes the steam turbine of FIG. 1, as seen in a cross section orthogonal to an axis of a rotor.

FIG. 3 is a front view showing an overall configuration example of a sealing device according to some embodiments.

FIG. 4A is an enlarged view of a part A of FIG. 3 surrounded by a broken line and shows a first movable mechanism of a first sealing device.

FIG. 4B is an enlarged view of the first movable mechanism when viewed from a radial outer side.

FIG. 4C is an exploded perspective view of the first movable mechanism.

FIG. 5 is a view showing only a first movable sealing member of the first sealing device shown in FIG. 4B.

FIG. 6A is a cross-sectional view taken along line B-B in FIGS. 4A and 9A and shows a state when the steam turbine is activated and deactivated.

FIG. 6B is a cross-sectional view taken along line C-C in FIGS. 4A and 9A and shows a state when the steam turbine is activated and deactivated.

FIG. 7A is a cross-sectional view taken along line B-B in FIGS. 4A and 9A and shows a state during rated operation of the steam turbine.

FIG. 7B is a cross-sectional view taken along line C-C in FIG. 4A and FIG. 9A and shows a state during rated operation of the steam turbine.

FIG. 8 is a cross-sectional view taken along line D-D in FIG. 4A and shows a state during rated operation of the steam turbine.

FIG. 9A is an enlarged view of the part A of FIG. 3 surrounded by the broken line and shows a second movable mechanism of a second sealing device.

FIG. 9B is an enlarged view of the second movable mechanism when viewed from the radial outer side.

FIG. 9C is an exploded perspective view of the second movable mechanism.

FIG. 10 is a view showing only the second movable sealing member of the second sealing device shown in FIG. 9B.

FIG. 11 is a cross-sectional view taken along line E-E in FIG. 9A and shows a state during rated operation of the steam turbine.

### DESCRIPTION OF EMBODIMENTS

Hereinafter, some embodiments of the present disclosure will be described with reference to the accompanying drawings. Dimensions, materials, shapes, relative arrangements, and the like of components described as embodiments or illustrated in the drawings are not intended to limit the scope of the present disclosure, but are merely explanatory examples.

For example, an expression representing a relative or absolute arrangement such as “in a certain direction”, “along a certain direction”, “parallel”, “orthogonal”, “center”, “concentric”, or “coaxial” does not strictly represent only such an arrangement, but also a tolerance or a state of being relatively displaced with an angle or a distance to the extent that the same function can be obtained.

For example, an expression such as “identical”, “equal”, or “homogeneous” representing a state where things are equal to each other does not strictly represent only the equal state, but also a tolerance or a state where there is a difference to the extent that the same function can be obtained.

For example, an expression representing a shape such as a quadrangular shape or a cylindrical shape does not represent only a shape such as a quadrangular shape or a cylindrical shape in a geometrically strict sense, but also a shape including an uneven portion, a chamfered portion, and the like within a range in which the same effect can be obtained.

Meanwhile, the expressions “being provided with”, “comprising”, “including”, or “having” one component are not exclusive expressions excluding the presence of other components.

### (Outline of Steam Turbine 1)

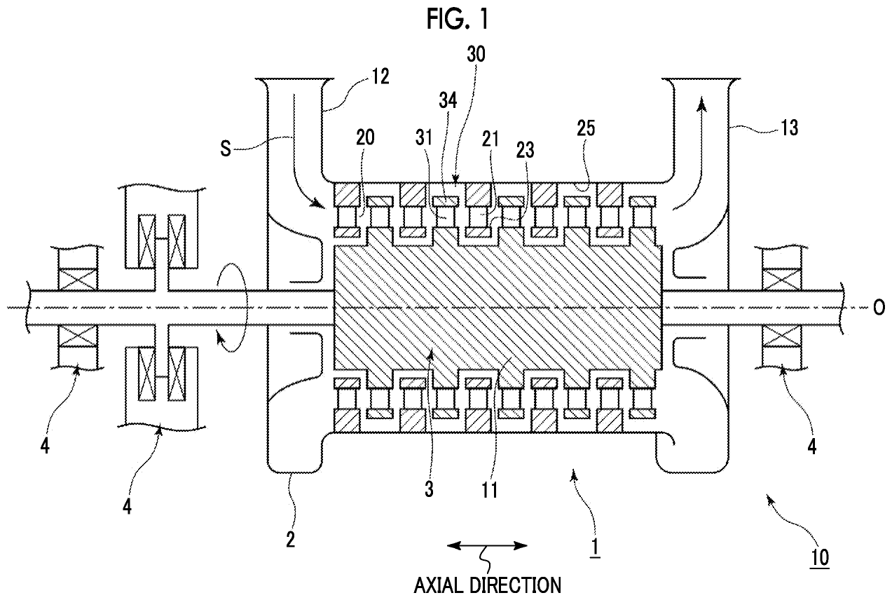

FIG. 1 is a diagram for describing a steam turbine as an example of a rotating machine including a sealing device according to some embodiments.

As shown in FIG. 1, a steam turbine plant 10 includes a steam turbine 1, a steam supply pipe 12 that supplies steam S as a working fluid to the steam turbine 1 from a steam supply source (not shown), and a steam discharge pipe 13 that is connected to a downstream side of the steam turbine 1 and that discharges the steam.

As shown in FIG. 1, the steam turbine 1 according to some embodiments includes a casing 2, a rotor main body 11 that rotates around an axis O in the casing 2, a rotor 3 that is connected to the rotor main body 11, and a bearing portion 4 that rotatably supports the rotor main body 11 around the axis O.

The rotor 3 includes a rotor main body 11 and a turbine rotor blade 30. The turbine rotor blade 30 includes a plurality of rotor blade main bodies 31 that are mounted to the rotor main body 11 to extend in a radial direction, and a tip shroud 34 that is connected to a tip portion of each of the plurality of rotor blade main bodies 31.

The casing 2 is a member having a substantially tubular shape provided to cover the rotor 3 from an outer peripheral side. The casing 2 is provided with a plurality of stator vane main bodies 21 that are mounted to extend to a radial inner side toward the rotor main body 11. A plurality of the stator vane main bodies 21 are arranged along a circumferential direction and an axis O direction on an inner peripheral surface 25. A hub shroud 23 that is connected to a tip portion of each of the plurality of stator vane main bodies 21 is mounted to each of the plurality of stator vane main bodies 21.

A main flow path 20 through which the steam S serving as the working fluid circulates is formed in a region inside the casing 2 where the stator vane main body 21 and the rotor blade main body 31 are arranged.

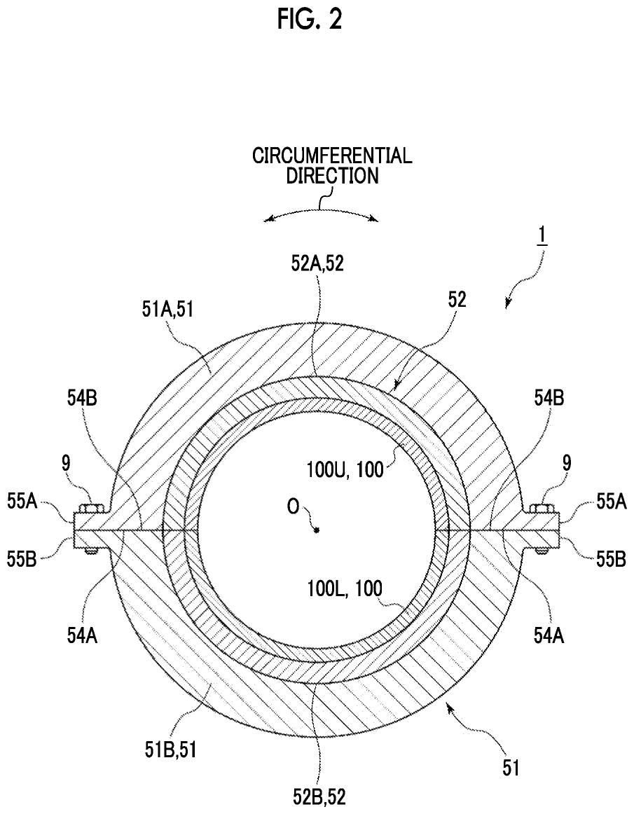

FIG. 2 is a schematic cross-sectional view of a casing main body that constitutes the steam turbine of FIG. 1, as seen in a cross section orthogonal to an axis of a rotor.

For convenience of description, in the following description, a radial direction around the axis O is referred to as a radial direction of the rotating member or simply as a radial direction. Similarly, in the following description, a circumferential direction around the axis O is referred to as a circumferential direction of the rotating member or simply a circumferential direction, and an extending direction of the axis O is referred to as an axial direction of the rotating member or simply an axial direction.

The casing 2 includes a casing main body (casing) 51 that defines a flow path of the steam S, and an annular vane ring 52 (refer to FIG. 2) that is fixed to an inner peripheral portion of the casing main body 51. Further, an inner peripheral portion of the vane ring 52 is provided with a sealing device 100 according to some embodiments.

The casing main body 51 is divided into a casing upper-half portion 51A and a casing lower-half portion 51B on a plane including the axis O of the rotor 3, as shown in FIG. 2. Each of the casing upper-half portion 51A and the casing lower-half portion 51B has a flange portion 55A or 55B protruding in the radial direction of the rotor 3 on a surface (split surface 54A or 54B) to be abutted against the counterpart, respectively. The casing upper-half portion 51A and the casing lower-half portion 51B are fastened to each other by bolts 9 in the flange portions 55A and 55B.

The schematic cross-sectional view shown in FIG. 2 shows the cross section of the casing main body 51 at an axial position where the turbine rotor blade 30 (refer to FIG. 1) is disposed on the radial inner side, and the casing main body 51 at the cross section position is formed in a cylindrical shape.

In addition, the vane ring 52 is also divided into a vane ring upper-half portion 52A and a vane ring lower-half portion 52B on a plane including the axis O of the rotor 3, as in the casing main body 51. The vane ring upper-half portion 52A is fixed to the casing upper-half portion 51A, and the vane ring lower-half portion 52B is fixed to the casing lower-half portion 51B. The casing upper-half portion 51A and the casing lower-half portion 51B are fastened and fixed to each other, so that the vane ring upper-half portion 52A and the vane ring lower-half portion 52B are connected to each other to form the vane ring 52.

The sealing device 100 according to some embodiments is divided into a sealing device upper-half portion 100U and a sealing device lower-half portion 100L, as in the casing main body 51 and the vane ring 52.

### (Regarding Sealing Device 100)

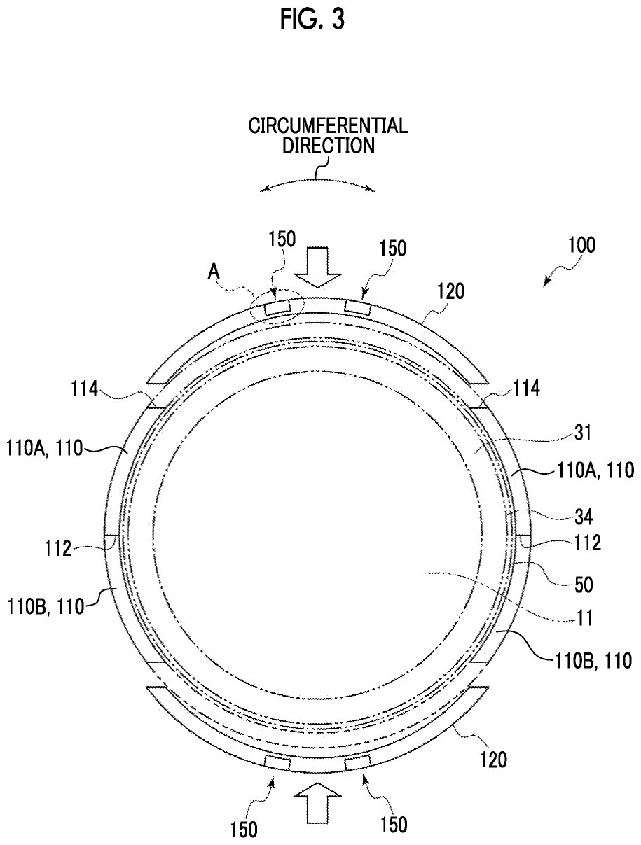

FIG. 3 is a front view showing an overall configuration example of the sealing device 100 according to some embodiments. As shown in FIG. 3, the sealing device 100 according to some embodiments includes a fixed sealing member 110 and a movable sealing member 120 that are provided in an annular shape along the tip shroud 34 connected to each of the tip portions of the plurality of rotor blade main bodies 31.

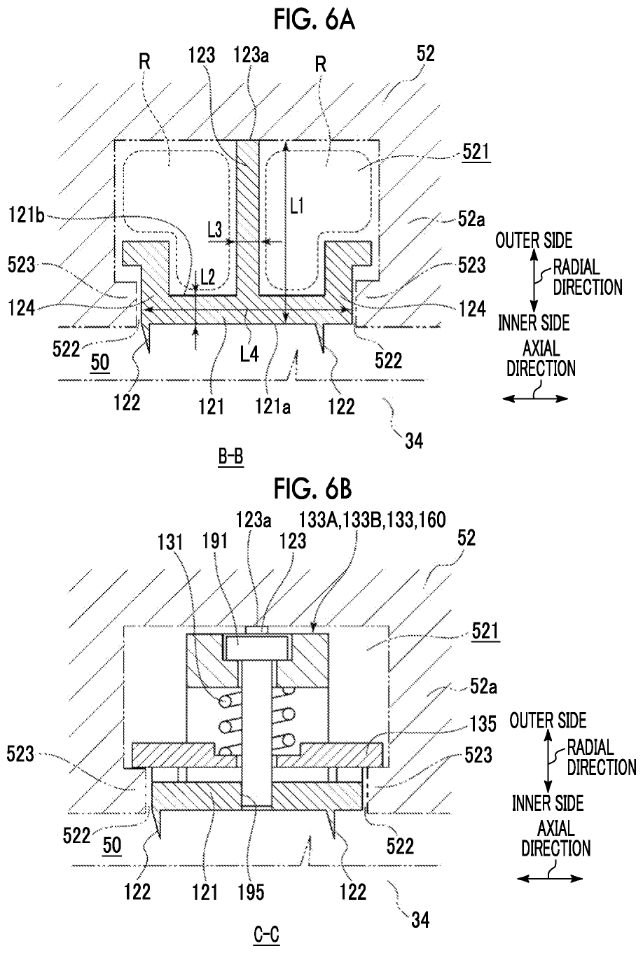

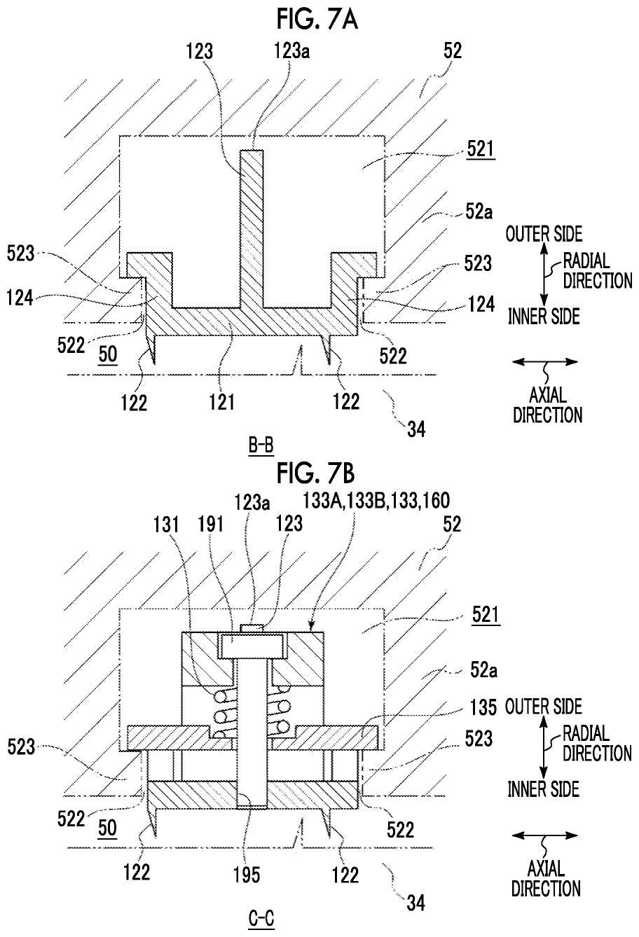

As well shown in FIGS. 6A, 6B, 7A, and 7B to be described later, the sealing device 100 according to some embodiments is held by a groove portion 521 formed in the vane ring 52 and extending in the circumferential direction, and is configured to seal a gap 50 between the tip shroud 34 and the vane ring 52.

Hereinafter, an example in which the sealing device 100 according to some embodiments is applied to a sealing device provided between the vane ring 52 as a “stationary member” of a rotating machine and the tip shroud 34 as a “rotating member” will be described. However, the sealing device 100 according to some embodiments can be used as various seals for rotating machines including a gland seal, a stator vane tip seal, a dummy ring seal, and the like.

In the fixed sealing member 110, a pair of an upper side member 110A and a lower side member 110B are respectively disposed on both left and right sides of the rotor main body 11. The upper side member 110A and the lower side member 110B that form a pair are abutted to each other at an abutment surface 112. A seal fin is provided on an inner peripheral side of the fixed sealing member 110, and leakage of a fluid (in a case where the rotating machine is the steam turbine 1, the fluid is steam S) between the fixed sealing member 110 and the tip shroud 34 is suppressed.

The fixed sealing member 110 is elastically supported by a leaf spring or the like from a back surface, and is configured to be able to escape to a radial outer side when the fixed sealing member 110 is in contact with the tip shroud 34. However, the fixed sealing member 110 is essentially immovable and does not move according to the operating state of the steam turbine 1.

Meanwhile, as will be described below, the movable sealing member 120 has a large gap 50 with the tip shroud 34 when the steam turbine 1 is activated and deactivated, and moves in an arrow direction in the drawing to come into contact with the fixed sealing member 110 at the abutment surface 114 during rated operation of the steam turbine, so that the gap 50 is narrowed.

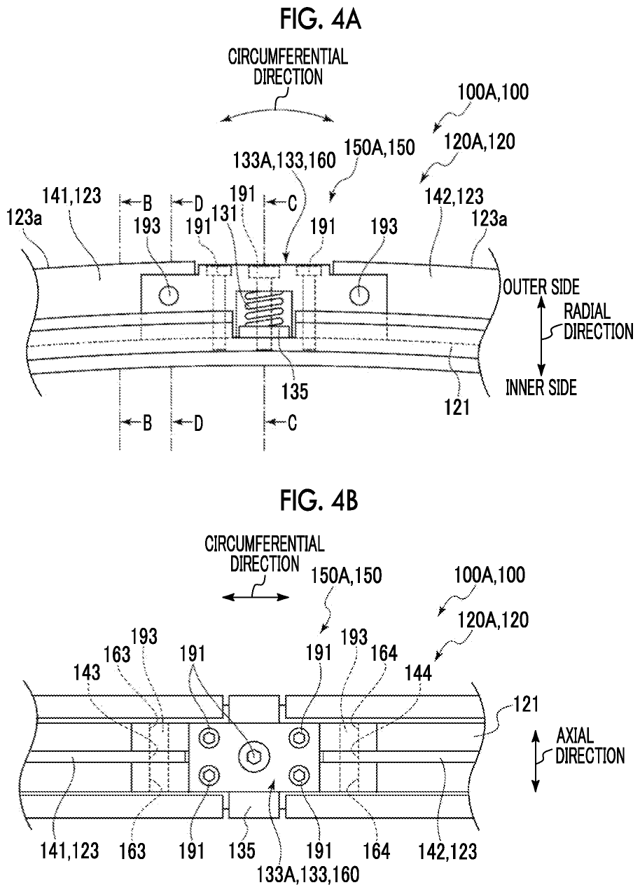

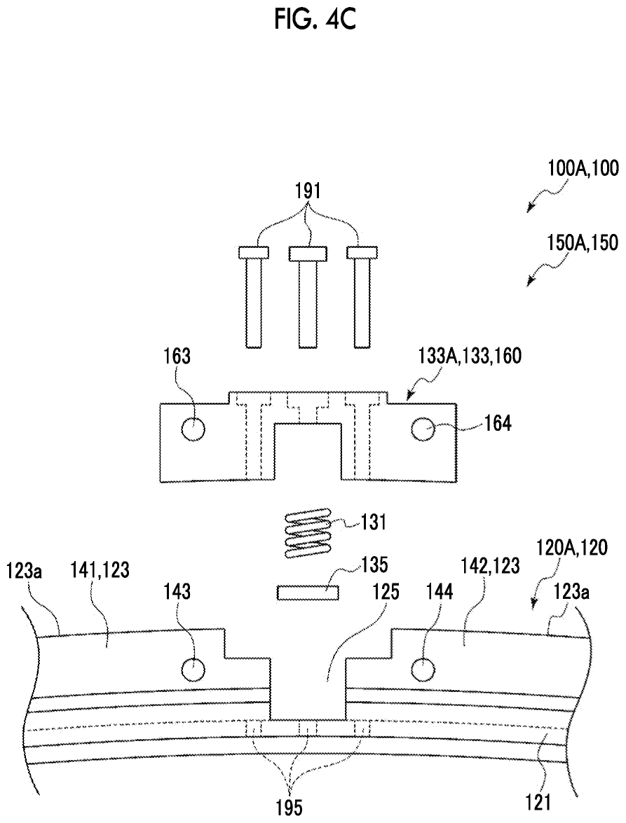

FIG. 4A is an enlarged view of a part A in FIG. 3 surrounded by a broken line and shows a first movable mechanism 150A of a first sealing device 100A which is the sealing device 100 according to the embodiment.

FIG. 4B is an enlarged view of the first movable mechanism 150A when viewed from the radial outer side.

FIG. 4C is an exploded perspective view of the first movable mechanism 150A.

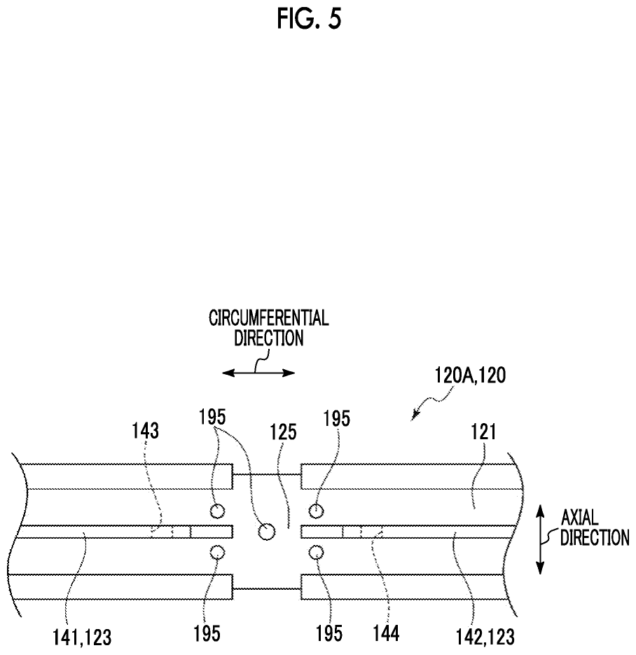

FIG. 5 is a view showing only a first movable sealing member 120A, which is the movable sealing member 120 of the first sealing device 100A, of the first sealing device 100A shown in FIG. 4B.

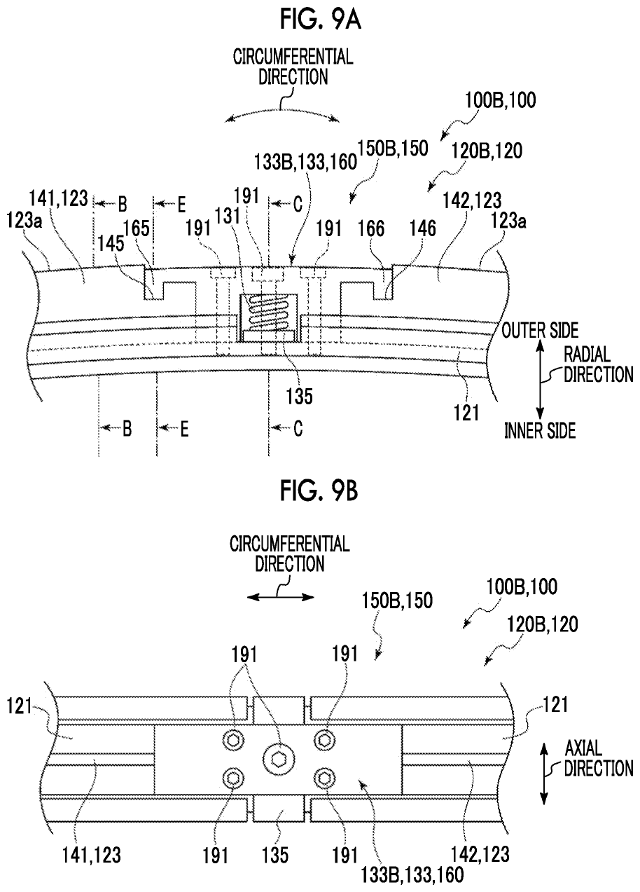

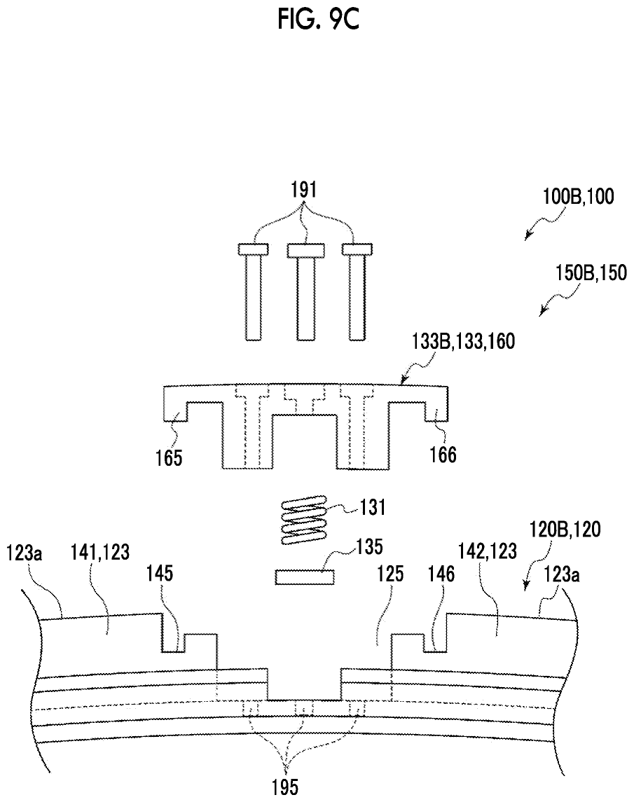

FIG. 6A is a cross-sectional view taken along line B-B in FIGS. 4A and 9A and shows a state when the steam turbine 1 is activated and deactivated.

FIG. 6B is a cross-sectional view taken along line C-C in FIGS. 4A and 9A and shows a state when the steam turbine 1 is activated and deactivated.

FIG. 7A is a cross-sectional view taken along line B-B in FIGS. 4A and 9A and shows a state during rated operation of the steam turbine 1.

FIG. 7B is a cross-sectional view taken along line C-C in FIGS. 4A and 9A and shows a state during rated operation of the steam turbine 1.

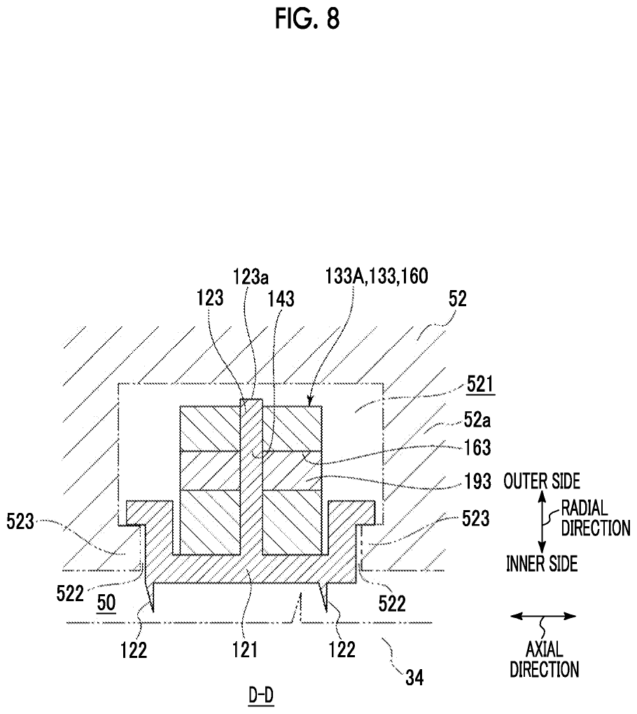

FIG. 8 is a cross-sectional view taken along line D-D in FIG. 4A and shows a state during rated operation of the steam turbine 1.

FIG. 9A is an enlarged view of the part A in FIG. 3 surrounded by a broken line and shows a second movable mechanism 150B of a second sealing device 100B which is a sealing device 100 according to another embodiment.

FIG. 9B is an enlarged view of the second movable mechanism 150B when viewed from the radial outer side.

FIG. 9C is an exploded perspective view of the second movable mechanism 150B.

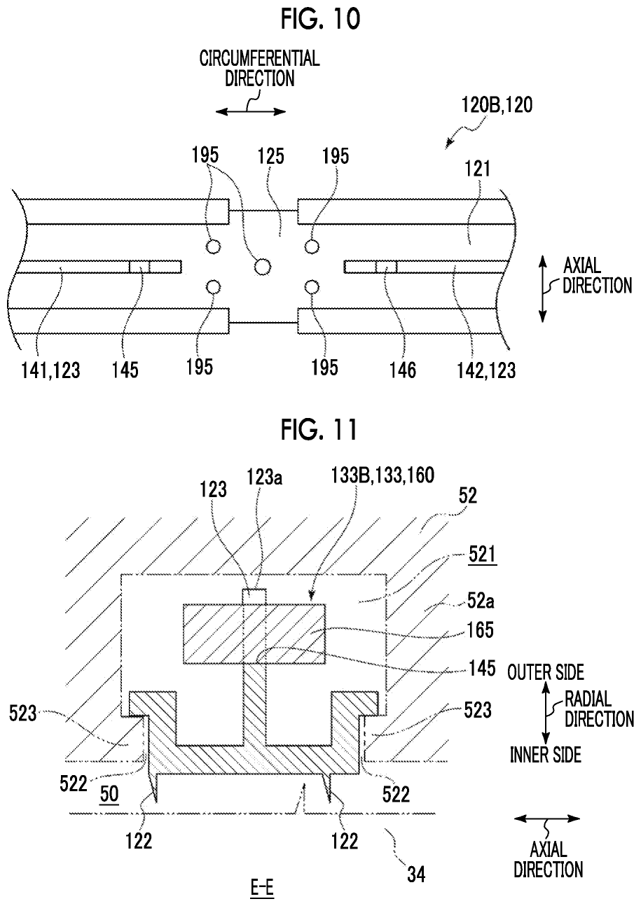

FIG. 10 is a view showing only a second movable sealing member 120B, which is the movable sealing member 120 of the second sealing device 100B, of the second sealing device 100B shown in FIG. 9B.

FIG. 11 is a cross-sectional view taken along line E-E in FIG. 9A and shows a state during rated operation of the steam turbine 1.

In the following description, when there is no particular need to distinguish between the first sealing device 100A according to one embodiment and the second sealing device 100B according to another embodiment, or when the first sealing device 100A according to one embodiment and the second sealing device 100B according to another embodiment are collectively described, the first sealing device 100A and the second sealing device 100B are simply referred to as the sealing device 100.

Similarly, in the following description, when there is no particular need to distinguish between the first movable mechanism 150A of the first sealing device 100A according to one embodiment and the second movable mechanism 150B of the second sealing device 100B according to another embodiment, or when the first movable mechanism 150A of the first sealing device 100A according to one embodiment and the second movable mechanism 150B of the second sealing device 100B according to another embodiment are collectively described, the first movable mechanism 150A and the second movable mechanism 150B are simply referred to as the movable mechanism 150.

In the following description, when there is no particular need to distinguish between the first movable sealing member 120A of the first sealing device 100A according to one embodiment and the second movable sealing member 120B of the second sealing device 100B according to another embodiment, or when the first movable sealing member 120A of the first sealing device 100A according to one embodiment and the second movable sealing member 120B of the second sealing device 100B according to another embodiment are collectively described, the first movable sealing member 120A and the second movable sealing member 120B are simply referred to as the movable sealing member 120.

The sealing device 100 according to some embodiments includes the movable sealing member 120 that is disposed between the tip shroud 34 and the vane ring 52 disposed on the radial outer side of the tip shroud 34 and that is a sealing member for sealing the gap 50 between the tip shroud 34 and the vane ring 52.

The sealing device 100 according to some embodiments includes a spring 131 as a biasing member that biases the movable sealing member 120 toward the radial outer side.

The sealing device 100 according to some embodiments includes a pressing plate 133 that presses the spring 131 from the radial outer side against a biasing force of the spring 131.

The sealing device 100 according to some embodiments includes a support plate 135 that supports the spring 131 from the radial inner side.

The first sealing device 100A according to one embodiment includes a first pressing plate 133A that presses the spring 131 from the radial outer side against the biasing force of the spring 131.

The second sealing device 100B according to another embodiment includes a second pressing plate 133B that presses the spring 131 from the radial outer side against the biasing force of the spring 131.

In the following description, when there is no particular need to distinguish between the first pressing plate 133A of the first sealing device 100A according to one embodiment and the second pressing plate 133B of the second sealing device 100B according to another embodiment, or when the first pressing plate 133A of the first sealing device 100A according to one embodiment and the second pressing plate 133B of the second sealing device 100B according to another embodiment are collectively described, the first pressing plate 133A and the second pressing plate 133B are simply referred to as the pressing plate 133.

In the first sealing device 100A according to the embodiment, the first movable mechanism 150A includes the spring 131, the first pressing plate 133A, and the support plate 135.

In the second sealing device 100B according to another embodiment, the second movable mechanism 150B includes the spring 131, the second pressing plate 133B, and the support plate 135.

In the sealing device 100 according to some embodiments, the pressing plate 133 is disposed on the radial outer side with respect to the movable sealing member 120, and is fixed to the movable sealing member 120 by a plurality of bolts 191 as joining members. As shown in FIG. 5, the movable sealing member 120 is formed with a female screw portion 195 that is screwed with a male screw of the bolt 191 in a base portion 121 to be described later.

In the sealing device 100 according to some embodiments, as shown in FIGS. 6A, 6B, 7A, 7B, 8, and 11, the movable sealing member 120 is held by the groove portion 521 formed in the vane ring 52.

A seal fin 122 is provided on an inner peripheral side of the movable sealing member 120, and the leakage of the steam S between the movable sealing member 120 and the tip shroud 34 is suppressed.

In the sealing device 100 according to some embodiments, as shown in FIGS. 6B, 7B, 8, and 11, the spring 131, the pressing plate 133, and the support plate 135 are provided inside the groove portion 521 of the vane ring 52.

In some embodiments, the groove portion 521 of the vane ring 52 is formed in an inner peripheral portion 52a of the vane ring 52 and extends in the circumferential direction. The groove portion 521 has an opening portion 522 that is open on the radial inner side.

In the vane ring 52, a pair of protrusion portions 523 protruding in the axial direction are formed so that a dimension of the opening portion 522 in the axial direction is smaller than a dimension of a region on the radial outer side of the groove portion 521 in the axial direction with respect to the opening portion 522.

In the sealing device 100 according to some embodiments, the support plate 135 abuts against the pair of protrusion portions 523 in the groove portion 521 from the radial outer side. Therefore, the movement of the support plate 135 toward the radial inner side in the groove portion 521 is restricted by the pair of protrusion portions 523.

In the sealing device 100 according to some embodiments, the spring 131 biases the support plate 135 toward the radial inner side and biases the pressing plate 133 toward the radial outer side.

Therefore, the movable sealing member 120 in which the pressing plate 133 is fixed is biased by the spring 131 so that a gap between the seal fin 122 and the tip shroud 34 is widened.

The spring 131 may be, for example, a coil spring, and any biasing member such as a disc spring, a leaf spring, or a metal bellows may be used instead of the coil spring.

### (When Steam Turbine 1 Is Activated and Deactivated)

When the steam turbine 1 is activated and deactivated, the steam S is not introduced into the groove portion 521, or even if the steam S is introduced, the pressure in the groove portion 521 is relatively low. Therefore, as shown in FIGS. 6A and 6B, in the sealing device 100 according to some embodiments, the movable sealing member 120 moves to the radial outer side by means of the biasing force of the spring 131. Accordingly, the gap between the seal fin 122 and the tip shroud 34 is widened.

### (During Rated Operation of Steam Turbine 1)

During rated operation of the steam turbine 1, the relatively high-pressure steam S is introduced into the groove portion 521, and the pressure in the groove portion 521 becomes relatively high. Therefore, as shown in FIGS. 7A and 7B, in the sealing device 100 according to some embodiments, the movable sealing member 120 moves to the radial outer side against the biasing force of the spring 131 by means of the pressure of the steam S in the groove portion 521. Accordingly, the gap between the seal fin 122 and the tip shroud 34 is narrowed.

### (Reliability of Operation of Movable Sealing Member 120)

In the sealing device upper-half portion 100U of the sealing device 100 according to some embodiments, the movable sealing member 120 needs to be moved vertically upward by the biasing force of the spring 131 against a self-weight of the movable sealing member 120. Therefore, in order to reliably secure the gap between the seal fin 122 and the tip shroud 34 when the steam turbine 1 is activated and deactivated, the biasing force of the spring 131 has to be sufficiently large. However, when the biasing force of the spring 131 is excessively large, it becomes difficult to displace the movable sealing member 120 to the radial inner side during the rated operation of the steam turbine 1.

In the sealing device 100 according to some embodiments, the dimension of the movable sealing member 120 in the radial direction is larger than the dimension of the gland seal, the stator vane tip seal, the dummy ring seal, or the like in the radial direction. Since the self-weight of the sealing member increases as the dimension of the movable sealing member 120 in the radial direction increases, the biasing force of the spring 131 has to be increased. Therefore, as the dimension of the movable sealing member 120 in the radial direction increases, it tends to become difficult to set the biasing force of the spring 131. Therefore, in the sealing device 100 according to some embodiments, it is difficult to set the biasing force of the spring 131 as compared with the biasing force of the gland seal, the stator vane tip seal, or the dummy ring seal.

In addition, in the sealing device upper-half portion 100U of the sealing device 100 according to some embodiments, the movable sealing member 120 needs to be displaced to the radial inner side against the self-weight of the movable sealing member 120 and the biasing force of the spring 131 during the rated operation of the steam turbine 1. Therefore, in order to reliably displace the movable sealing member 120 to the radial inner side during the rated operation of the steam turbine 1, the biasing force of the spring 131 has to be relatively small. However, when the biasing force of the spring 131 is excessively small, it becomes difficult to secure the gap between the seal fin 122 and the tip shroud 34 when the steam turbine 1 is activated and deactivated. Therefore, as the dimension of the movable sealing member 120 in the radial direction increases, it tends to become difficult to set the biasing force of the spring 131.

Therefore, in the sealing device 100 according to some embodiments, the movable sealing member 120 is configured as follows so that the self-weight of the movable sealing member 120 is suppressed while the rigidity of the movable sealing member 120 is secured.

That is, in the sealing device 100 according to some embodiments, for example, as shown in FIGS. 4A, 4B, 4C, 5, 6A, 6B, 7A, 7B, 8, 9A, 9B, 9C, 10, and 11, the movable sealing member 120 has the base portion 121 extending in the circumferential direction.

In the sealing device 100 according to some embodiments, for example, as shown in FIGS. 4A, 4B, 4C, 5, 6A, 6B, 7A, 7B, 8, 9A, 9B, 9C, 10, and 11, the movable sealing member 120 includes a rib 123 that extends in the circumferential direction and that protrudes from the base portion 121 toward the radial outer side.

In the sealing device 100 according to some embodiments, for example, as shown in FIGS. 4A, 4C, 6A, 6B, 7A, 7B, 8, 9A, 9C, and 11, the movable sealing member 120 includes the seal fin 122 that extends in the circumferential direction and that protrudes from the base portion 121 toward the radial inner side.

In the sealing device 100 according to some embodiments, for example, as shown in FIGS. 4C, 5, 9C, and 10, the rib 123 includes a notch portion 125 in which the spring 131 is disposed between one end and the other end of the rib 123 in the circumferential direction.

In the sealing device 100 according to some embodiments, the ribs 123 are provided on the movable sealing member 120, whereby the self-weight of the movable sealing member 120 can be suppressed while the rigidity of the movable sealing member 120 is secured. Accordingly, when the steam turbine 1 is activated and deactivated, the gap between the tip shroud 34 and the seal fin 122, which is the seal gap between the tip shroud 34 as the rotating member and the movable sealing member 120, is easily secured, and during the rated operation of the steam turbine 1, the amount of leakage of the steam S, which is the working fluid, can be reduced.

The steam turbine 1 according to some embodiments includes the tip shroud 34 as a rotating member, the vane ring 52 as a stationary member, and the sealing device 100 according to some embodiments.

Accordingly, when the steam turbine 1 is activated and deactivated, the gap between the tip shroud 34 and the seal fin 122, which is the seal gap between the tip shroud 34 as the rotating member and the movable sealing member 120, is easily secured, and during the rated operation of the steam turbine 1, the amount of leakage of the steam S, which is the working fluid, can be reduced.

In the sealing device 100 according to some embodiments, a distance L1 from a radial inner surface 121a of the base portion 121 to a radial outer end surface 123a of the rib 123 may be three times or more a distance L2 from the radial inner surface 121a of the base portion 121 to a radial outer surface 121b of the base portion 121.

Accordingly, a region R where the portion constituting the movable sealing member 120 is not present on both sides in the axial direction with the rib 123 interposed therebetween can be provided. Therefore, the self-weight of the movable sealing member 120 can be reduced by the amount corresponding to this region. According to the sealing device 100 according to some embodiments, with respect to the thickness (distance L2) of the base portion 121 in the radial direction, the length of the rib 123 in the radial direction ((distance L1)−(distance L2)) is relatively large. Therefore, the region R is relatively large, and the self-weight of the movable sealing member 120 is relatively small. Accordingly, when the steam turbine 1 is activated and deactivated, the gap between the tip shroud 34 and the seal fin 122, which is the seal gap between the tip shroud 34 as the rotating member and the movable sealing member 120, is easily secured, and during the rated operation of the steam turbine 1, the amount of leakage of the steam S, which is the working fluid, can be reduced.

In the sealing device 100 according to some embodiments, the base portion 121 may include an insertion portion 124 inserted into the opening portion 522 in the groove portion 521 extending in the circumferential direction, the groove portion 521 being formed in the inner peripheral portion 52a of the vane ring 52 serving as the stationary member. A dimension L3 of the rib 123 in the axial direction may be 0.3 times or less a dimension L4 of the insertion portion 124 in the axial direction.

Accordingly, a region R where the portion constituting the movable sealing member 120 is not present on both sides in the axial direction with the rib 123 interposed therebetween can be provided. Therefore, the self-weight of the movable sealing member 120 can be reduced by the amount of the region R. According to the sealing device 100 according to some embodiments, the thickness (dimension L3) of the rib 123 with respect to the dimension in the axial direction (dimension L4) of the base portion 121 is relatively small. Therefore, the region R is relatively large, and the self-weight of the movable sealing member 120 is relatively small.

Accordingly, when the steam turbine 1 is activated and deactivated, the gap between the tip shroud 34 and the seal fin 122, which is the seal gap between the tip shroud 34 as the rotating member and the movable sealing member 120, is easily secured, and during the rated operation of the steam turbine 1, the amount of leakage of the steam S, which is the working fluid, can be reduced.

### (Reinforcement of Rib 123)

In the sealing device 100 according to some embodiments, in the region where the notch portion 125 is present, the height of the rib 123 (dimension in the radial direction) is lower than that in the other region, or the rib 123 is not present. Therefore, the base portion 121 at the circumferential position where the notch portion 125 is present is easily deformed to be bent along a virtual plane extending in the radial direction as compared with other regions where the notch portion 125 is not present.

Therefore, the sealing device 100 according to some embodiments may include a restricting member 160 that is a member different from the movable sealing member 120 and that restricts deformation of the base portion 121 at the circumferential position where the notch portion 125 is present.

Accordingly, the deformation of the base portion 121 at the circumferential position where the notch portion 125 is present is restricted by the restricting member 160. Therefore, the rigidity of the movable sealing member 120 can be secured even when the notch portion 125 is provided.

In the sealing device 100 according to some embodiments, the restricting member 160 may be the pressing plate 133 that presses the spring 131 from the radial outer side against the biasing force of the spring 131 as the biasing member.

Accordingly, the restricting member 160 may not be newly provided as a member separate from the pressing plate 133, and the rigidity of the movable sealing member 120 can be secured by the pressing plate 133.

In the sealing device 100 according to some embodiments, the restricting member 160 may be fixed to the base portion on one side in the circumferential direction and to the base portion 121 on the other side in the circumferential direction with the notch portion 125 interposed therebetween by the joining member. In the sealing device 100 according to some embodiments, for example, as shown in FIGS. 4A, 4B, 4C, 9A, 9B, and 9C, the restricting members 160 are fixed to the base portion 121 by the bolts 191 at a total of four locations, that is, each of one side and the other side in the circumferential direction with the notch portion 125 interposed therebetween and each of one side and the other side in the axial direction with the rib 123 interposed therebetween. In addition, in the sealing device 100 according to some embodiments, for example, as shown in FIGS. 4A, 4B, 4C, 9A, 9B, and 9C, the restricting member 160 is fixed to the base portion 121 by the bolt 191 at one location at the circumferential position where the notch portion 125 is provided.

Accordingly, the restricting member 160 can be stably fixed to the movable sealing member 120.

In the sealing device 100 according to some embodiments, the restricting member 160 may extend from one side to the other side in the axial direction with the rib 123 interposed therebetween.

In the sealing device 100 according to some embodiments, the restricting members 160 are present on one side and the other side in the axial direction with the rib 123 interposed therebetween, whereby the reinforcement can be performed by being balanced in the axial direction with a relatively simple configuration. In addition, in the sealing device 100 according to some embodiments, the rigidity of the movable sealing member 120 in the circumferential direction can also be stably reinforced.

### (Joining Between Restricting Member 160 and Rib 123)

In the sealing device 100 according to some embodiments, for example, as well shown in FIGS. 4C and 9C, the rib 123 may include a first rib 141 on one side and a second rib 142 on the other side in the circumferential direction with the notch portion 125 interposed therebetween. The restricting member 160 may be joined to the first rib 141 and the second rib 142 in a form to be described later.

Accordingly, the restricting member 160 restricts the relative movement between the first rib 141 and the second rib 142, so that the deformation of the base portion 121 at the circumferential position where the notch portion 125 is present can be suppressed. Accordingly, the rigidity of the movable sealing member 120 can be secured even when the notch portion 125 is provided.

### (Case of First Sealing Device 100A According to One Embodiment)

In the first sealing device 100A according to the embodiment, for example, as shown in FIGS. 4A, 4B, 4C, 5, and 8, the first rib 141 may be provided with a first through-hole 143 penetrating the first rib 141 in the axial direction. The second rib 142 may be provided with a second through-hole 144 penetrating the second rib 142 in the axial direction.

In the first sealing device 100A according to one embodiment, for example, as shown in FIGS. 4A, 4B, 4C, and 8, the restricting member 160 may be provided with third through-holes 163 penetrating the restricting member 160 in the axial direction and fourth through-holes 164 penetrating the restricting member in the axial direction at a position separated from the third through-holes 163 in the circumferential direction.

The first sealing device 100A according to one embodiment may include, for example, at least two joining pins 193 that join the restricting member 160 and the first rib 141 and the second rib 142 to each other, as shown in FIGS. 4A and 4B. At least one of the joining pins 193 may be inserted into the first through-hole 143 and the third through-holes 163, and at least another one of the joining pins 193 may be inserted into the second through-hole 144 and the fourth through-holes 164.

In addition, in the exploded perspective view of FIG. 4C, the description of the joining pin 193 is omitted.

In the first sealing device 100A according to the embodiment, the rigidity of the movable sealing member 120 can be relatively easily secured by a relatively simple configuration in which the restricting member 160 and the first rib 141 and the second rib 142 are joined by the joining pin 193.

In the first sealing device 100A according to the embodiment, the third through-holes 163 may be provided on one side and the other side in the axial direction with the first rib 141 interposed therebetween, and the fourth through-holes 164 may be provided on one side and the other side in the axial direction with the second rib 142 interposed therebetween, in the restricting member 160. That is, the restricting member 160 may be present on one side and the other side in the axial direction with the first rib 141 and the second rib 142 interposed therebetween, and may be connected to the one side and the other side in the axial direction with the first rib 141 and the second rib 142 interposed therebetween via the joining pin 193.

In the first sealing device 100A according to the embodiment, the restricting members 160 are present on one side and the other side in the axial direction with the first rib 141 and the second rib 142 interposed therebetween, whereby the reinforcement can be performed by being balanced in the axial direction with a relatively simple configuration. In addition, according to the first sealing device 100A according to the embodiment, the rigidity of the movable sealing member 120 in the circumferential direction can also be stably reinforced.

### (Case of Second Sealing Device 100B According to Other Embodiment)

In the second sealing device 100B according to another embodiment, for example, as shown in FIGS. 9A, 9C, 10, and 11, the first rib 141 may be formed with a first recessed portion 145 recessed toward the radial inner side. In the second sealing device 100B according to another embodiment, for example, as shown in FIGS. 9A, 9C, 10, and 11, the second rib 142 may be formed with a second recessed portion 146 recessed toward the radial inner side. In the second sealing device 100B according to another embodiment, for example, as shown in FIGS. 9A, 9C, and 11, the restricting member 160 may have a first protrusion portion 165 fitted to the first recessed portion 145 and a second protrusion portion 166 fitted to the second recessed portion 146.

Accordingly, the rigidity of the movable sealing member 120 can be relatively easily secured with a relatively simple configuration in which the restricting member 160 and the first rib 141 and the second rib 142 are joined to each other by fitting the first protrusion portion 165 and the first recessed portion 145 to each other and fitting the second protrusion portion 166 and the second recessed portion 146 to each other.

The present disclosure is not limited to the above-described embodiments, and includes a modification of the above-described embodiments and an appropriate combination of the embodiments.

For example, in the above description, a case where the sealing device 100 according to some embodiments is applied to the steam turbine 1 as an example of the rotating machine has been described. However, the sealing device 100 according to some embodiments may be applied to other rotating machines such as a gas turbine.

The contents described in each embodiment are understood as follows, for example.

(1) A sealing device 100 according to at least one embodiment of the present disclosure includes a movable sealing member 120 that is disposed between a tip shroud 34 serving as a rotating member of a steam turbine 1 as a rotating machine and a vane ring 52 serving as a stationary member disposed on a radial outer side of the rotating member with respect to the tip shroud 34 serving as the rotating member, and that is a sealing member sealing between the rotating member (tip shroud 34) and the stationary member (vane ring 52); and a spring 131 serving as a biasing member that biases the sealing member (movable sealing member 120) toward the radial outer side. The sealing member (movable sealing member 120) includes a base portion 121 extending in a circumferential direction of the rotating member, a rib 123 extending in the circumferential direction and protruding from the base portion 121 toward the radial outer side, and a seal fin 122 extending in the circumferential direction and protruding from the base portion 121 toward a radial inner side of the rotating member. The rib 123 includes a notch portion 125 in which a biasing member (spring 131) is disposed between one end and the other end of the rib 123 in the circumferential direction.

According to the configuration of (1), the rib 123 described above is provided on the sealing member (movable sealing member 120). In this manner, a self-weight of the sealing member (movable sealing member 120) can be suppressed while the rigidity of the sealing member (movable sealing member 120) is secured. As a result, a seal gap between the rotating member (the tip shroud 34) and the sealing member (the movable sealing member 120) is easily secured when the rotating machine (the steam turbine 1) is activated and deactivated, and the amount of leakage of steam S as the working fluid can be reduced during the operation of the rotating machine (the steam turbine 1).

(2) In some embodiments, in the configuration of (1) described above, a distance L1 from a radial inner surface 121a of the base portion 121 to a radial outer end surface 123a of the rib 123 may be three times or more a distance L2 from the radial inner surface 121a of the base portion 121 to a radial outer surface 121b of the base portion 121.

According to the configuration of (2) described above, a region R where the portion that forms the sealing member (movable sealing member 120) is not present on both sides in an axial direction with the rib 123 interposed therebetween can be provided. Therefore, the self-weight of the sealing member (movable sealing member 120) can be reduced by the amount of the region R. According to the configuration of (2) described above, with respect to the thickness (distance L2) of the base portion 121 in a radial direction, the length of the rib 123 in the radial direction ((distance L1)−(distance L2)) is relatively large. Therefore, the region R is relatively large, and the self-weight of the sealing member (movable sealing member 120) is relatively small. As a result, the seal gap between the rotating member (tip shroud 34) and the sealing member (movable sealing member 120) is easily secured when the rotating machine (the steam turbine 1) is activated and deactivated, and amount of leakage of the working fluid (steam S) can be reduced during the operation of the rotating machine (the steam turbine 1).

(3) In some embodiments, in the configuration of (1) or (2) described above, the base portion 121 may include an insertion portion 124 inserted into an opening portion 522 in a groove portion 521 extending in the circumferential direction, the groove portion 521 being formed in an inner peripheral portion 52a of the stationary member (vane ring 52). A dimension L3 of the rib 123 of the rotating member in the axial direction may be 0.3 times or less a dimension L4 of the insertion portion 124 in the axial direction.

According to the configuration of (3) described above, a region R where the portion that forms the sealing member (movable sealing member 120) is not present on both sides in the axial direction with the rib 123 interposed therebetween can be provided. Therefore, the self-weight of the sealing member (movable sealing member 120) can be reduced by the amount of the region R. According to the configuration of (3) described above, the thickness (dimension L3) of the rib 123 with respect to the dimension in the axial direction (dimension L4) of the base portion 121 is relatively small. Therefore, the region R is relatively large, and the self-weight of the sealing member (movable sealing member 120) is relatively small. As a result, the seal gap between the rotating member (tip shroud 34) and the sealing member (movable sealing member 120) is easily secured when the rotating machine (the steam turbine 1) is activated and deactivated, and amount of leakage of the working fluid (steam S) can be reduced during the operation of the rotating machine (the steam turbine 1).

(4) In some embodiments, in any one of the configurations of (1) to (3) described above, a restricting member 160 that is a member different from the sealing member (movable sealing member 120) and that restricts deformation of the base portion 121 at a circumferential position where the notch portion 125 is present may be included.

In the region where the notch portion 125 is present, the height of the rib 123 is lower than that in other regions, or the rib 123 is not present. Therefore, the base portion 121 at the circumferential position where the notch portion 125 is present is easily deformed to be bent along a virtual plane extending in the radial direction as compared with other regions where the notch portion 125 is not present.

According to the configuration of (4) described above, the deformation of the base portion 121 at the circumferential position where the notch portion 125 is present is restricted by the restricting member 160. Therefore, the rigidity of the sealing member (movable sealing member 120) can be secured even when the notch portion 125 is provided.

(5) In some embodiments, in the configuration of (4) described above, the rib 123 may include a first rib 141 on one side and a second rib 142 on the other side in the circumferential direction with the notch portion 125 interposed therebetween. The restricting member 160 may be joined to the first rib 141 and the second rib 142.

According to the configuration of (5), the restricting member 160 restricts the relative movement between the first rib 141 and the second rib 142, so that the deformation of the base portion 121 at the circumferential position where the notch portion 125 is present can be suppressed. Accordingly, the rigidity of the sealing member (movable sealing member 120) can be secured even when the notch portion 125 is provided.

(6) In some embodiments, in the configuration of (5) described above, the first rib 141 may be provided with a first through-hole 143 penetrating the first rib 141 in an axial direction of the rotating member. The second rib 142 may be provided with a second through-hole 144 penetrating the second rib 142 in the axial direction. The restricting member 160 may be provided with third through-holes 163 penetrating the restricting member 160 in the axial direction and fourth through-holes 164 penetrating the restricting member 160 in the axial direction at a position separated from the third through-holes 163 in the circumferential direction. The sealing device 100 may include at least two joining pins 193 that join the restricting member 160 and the first rib 141 and the second rib 142 to each other. At least one of the joining pins 193 may be inserted into the first through-hole 143 and the third through-holes 163, and at least another one of the joining pins 193 may be inserted into the second through-hole 144 and the fourth through-holes 164.

According to the configuration of (6), the rigidity of the sealing member (movable sealing member 120) can be relatively easily secured by a relatively simple configuration in which the restricting member 160 and the first rib 141 and the second rib 142 are joined by the joining pin 193.

(7) In some embodiments, in the configuration of (6) described above, the third through-holes 163 may be provided on one side and the other side in the axial direction with the first rib 141 interposed therebetween, and the fourth through-holes 164 may be provided on one side and the other side in the axial direction with the second rib 142 interposed therebetween, in the restricting member 160.

According to the configuration of (7) described above, the restricting members 160 are present on one side and the other side in the axial direction with the first rib 141 and the second rib 142 interposed therebetween, whereby the reinforcement can be performed by being balanced in the axial direction with a relatively simple configuration. In addition, according to the configuration of (7) described above, the rigidity of the sealing member (movable sealing member 120) in the circumferential direction can also be stably reinforced.

(8) In some embodiments, in the configuration of (5) described above, the first rib 141 may be formed with a first recessed portion 145 recessed toward the radial inner side. The second rib 142 may be formed with a second recessed portion 146 recessed toward the radial inner side. The restricting member 160 may have a first protrusion portion 165 that is fitted to the first recessed portion 145 and a second protrusion portion 166 that is fitted to the second recessed portion 146.

According to the configuration of (8) described above, the rigidity of the sealing member (movable sealing member 120) can be relatively easily secured with a relatively simple configuration in which the restricting member 160 and the first rib 141 and the second rib 142 are joined to each other by fitting the first protrusion portion 165 and the first recessed portion 145 to each other and fitting the second protrusion portion 166 and the second recessed portion 146 to each other.

(9) In some embodiments, in any one of the configurations (4) to (8) described above, the restricting member 160 may be fixed to the base portion on one side in the circumferential direction and to the base portion 121 on the other side in the circumferential direction with the notch portion 125 interposed therebetween by the joining member (bolt 191).

According to the configuration of (9) described above, the restricting member 160 can be stably fixed to the sealing member (movable sealing member 120).

(10) In some embodiments, in any one of the configurations (4) to (9) described above, the restricting member 160 may extend from one side to the other side in an axial direction of the rotating member with the rib 123 interposed therebetween.

According to the configuration (10) described above, the restricting members 160 are present on one side and the other side in the axial direction with the rib 123 interposed therebetween, whereby the reinforcement can be performed by being balanced in the axial direction with a relatively simple configuration. In addition, according to the configuration of (10) described above, the rigidity of the sealing member (movable sealing member 120) in the circumferential direction can also be stably reinforced.

(11) In some embodiments, in any one of the configurations (4) to (10) described above, the restricting member 160 may be a pressing plate 133 that presses the biasing member (spring 131) from the radial outer side against a biasing force of the biasing member (spring 131).

According to the configuration of (11) described above, the restricting member 160 may not be newly provided as a member separate from the pressing plate 133, and the rigidity of the movable sealing member 120 can be secured by the pressing plate 133.

(12) A rotating machine according to at least one embodiment of the present disclosure includes the tip shroud 34 as the rotating member, the vane ring 52 as the stationary member, and the sealing device 100 having any one of the configurations of (1) to (11).

According to the configuration of (12) described above, the seal gap between the rotating member (tip shroud 34) and the sealing member (movable sealing member 120) is easily secured when the rotating machine (the steam turbine 1) is activated and deactivated, and the amount of leakage of the working fluid (steam S) can be reduced during the operation of the rotating machine (the steam turbine 1).

### REFERENCE SIGNS LIST

1: Steam turbine
34: Tip shroud
52: Vane ring
52a: Inner peripheral portion
100: Sealing device
120: Movable sealing member
121: Base portion
121a: Surface
121b: Surface
122: Seal fin
123: Rib
123a: End surface
124: Insertion portion
125: Notch portion
131: Spring
141: First rib
142: Second rib
143: First through-hole
144: Second through-hole
145: First recessed portion
146: Second recessed portion
160: Restricting member
163: Third through-hole
164: Fourth through-hole
165: First protrusion portion
166: Second protrusion portion
191: Bolt
193: Joining pin
521: Groove portion
522: Opening portion

1. A sealing device comprising:
a sealing member that is disposed between a rotating member of a rotating machine and a stationary member disposed on a radial outer side of the rotating member with respect to the rotating member, and that seals between the rotating member and the stationary member; and
a biasing member that biases the sealing member toward the radial outer side,
wherein the sealing member includes
a base portion that extends in a circumferential direction of the rotating member,
a rib that extends in the circumferential direction and that protrudes from the base portion toward the radial outer side, and
a seal fin that extends in the circumferential direction and that protrudes from the base portion toward a radial inner side of the rotating member, and
the rib has a notch portion in which the biasing member is disposed between one end and the other end of the rib in the circumferential direction.

2. The sealing device according to claim 1,
wherein a distance from a surface on the radial inner side of the base portion to an end surface on the radial outer side of the rib is three times or more a distance from the surface on the radial inner side of the base portion to a surface on the radial outer side of the base portion.

3. The sealing device according to claim 1,
wherein the base portion includes an insertion portion inserted into an opening portion of a groove portion formed in an inner peripheral portion of the stationary member and extending in the circumferential direction, and
a dimension of the rib of the rotating member in an axial direction is 0.3 times or less a dimension of the insertion portion in the axial direction.

4. The sealing device according to claim 1, further comprising:
a restricting member that is a member different from the sealing member and that restricts deformation of the base portion at a circumferential position where the notch portion is present.

5. The sealing device according to claim 4,
wherein the rib includes a first rib on one side and a second rib on the other side in the circumferential direction with the notch portion interposed therebetween, and
the restricting member is joined to the first rib and the second rib.

6. The sealing device according to claim 5,
wherein the first rib is provided with a first through-hole penetrating the first rib in an axial direction of the rotating member,
the second rib is provided with a second through-hole penetrating the second rib in the axial direction,
the restricting member is provided with third through-holes penetrating the restricting member in the axial direction, and fourth through-holes penetrating the restricting member in the axial direction at a position separated from the third through-holes in the circumferential direction,
the sealing device further comprises at least two joining pins joining the restricting member to the first rib and the second rib,
at least one of the joining pins is inserted into the first through-hole and the third through-holes, and
at least another one of the joining pins is inserted into the second through-hole and the fourth through-holes.

7. The sealing device according to claim 6,
wherein the restricting member has the third through-holes provided on one side and the other side in the axial direction with the first rib interposed therebetween, and the fourth through-holes provided on one side and the other side in the axial direction with the second rib interposed therebetween.

8. The sealing device according to claim 5,
wherein a first recessed portion recessed toward the radial inner side is formed in the first rib, a second recessed portion recessed toward the radial inner side is formed in the second rib, and the restricting member has a first protrusion portion fitted to the first recessed portion and a second protrusion portion fitted to the second recessed portion.

9. The sealing device according to claim 4,
wherein the restricting member is fixed to the base portion on one side in the circumferential direction and to the base portion on the other side in the circumferential direction with the notch portion interposed therebetween by a joining member.

10. The sealing device according to claim 4,
wherein the restricting member extends from one side to the other side of the rotating member in an axial direction with the rib interposed therebetween.

11. The sealing device according to claim 4,
wherein the restricting member is a pressing plate that presses the biasing member from the radial outer side against a biasing force of the biasing member.

12. A rotating machine comprising:
the rotating member;
the stationary member; and
the sealing device according to claim 1.
